(19) United States
(12) Patent Application Publication
(10) Pub. No.: US 2007/0244657 A1
(43) Pub. Date: Oct. 18, 2007

(54) Methods and systems for testing radio frequency identification (RFID) tags having multiple antennas

(76) Inventors: Randall Allen Drago, Gaithersburg, MD (US); Ming-Hao Sun, Gaithersburg, MD (US); Theodore Hockey, Mount Airy, MD (US); Joseph White, Woodbine, MD (US)

Correspondence Address: STERNE, KESSLER, GOLDSTEIN & FOX P.L.L.C., 1100 NEW YORK AVENUE, N.W., WASHINGTON, DC, 20005, US

(21) Appl. No.: 11/401,350

(22) Filed: Apr. 11, 2006

(51) Int. Cl. G01N 37/00; G01R 31/00; G08B 13/14

(52) U.S. Cl. 702/81; 340/572.7; 324/500

(57) ABSTRACT

Methods, systems, and apparatuses for testing antenna(s) of a radio frequency identification (RFID) tag are described. A reader transmits a test command signal to a RFID tag having a plurality of antennas. Each antenna of the plurality of antennas is coupled to a respective antenna port. The tag processes the test command signal to determine which one or more of the plurality of antennas is to be tested. The tag couples an information signal to the antenna port(s) corresponding with the antenna(s) to be tested. For example, the tag may include enabling elements that selectively couple the information signal to respective antenna ports based on respective test control signals. The RFID tag generates the test control signals based on the test command signal. The reader awaits receipt of the information signal from the RFID tag.

### BACKGROUND OF THE INVENTION

1. Field of the Invention

The present invention relates generally to radio frequency identification (RFID) tags, and more specifically to testing RFID tags.

2. Related Art

Many product-related and service-related industries entail the use and/or sale of large numbers of useful items. In such industries, it may be advantageous to have the ability to monitor the items that are located within a particular range. For example, it may be desirable to determine the presence of inventory items on a shelf or elsewhere in a store or a warehouse.

Radio frequency identification (RFID) tags are electronic devices that may be affixed to items whose presence is to be detected and/or monitored.

The presence of an RFID tag, and therefore the presence of an item to which the tag is affixed, may be checked and monitored wirelessly by devices known as “readers.” Readers typically have one or more antennas, transmitting radio frequency (RF) signals to which tags respond. A reader is sometimes referred to as a “reader interrogator” or simply an “interrogator” because the reader “interrogates” RFID tags and receives signals back from the tags in response to the interrogation. Typically, each tag has a unique identification number that the reader uses to identify the particular tag and item.

Readers may test the operability of tags by transmitting an RF signal and determining whether responses are received from the tags. Many conventional tags include multiple antennas. However, conventional readers are not capable of separately testing the antennas of a tag that has multiple antennas. Moreover, conventional tags are not capable of facilitating such testing.

What is needed, then, is a method and system that addresses the aforementioned shortcomings of conventional readers, tags, and testing systems and methods.

### SUMMARY OF THE INVENTION

The present invention is directed to methods, systems, and apparatuses for testing antenna(s) of a radio frequency identification (RFID) tag. Each antenna of the RFID tag is coupled to a respective antenna port. A reader transmits a test command signal to the tag. The test command signal includes information indicating which one or more of the antenna(s) is to be tested. The tag processes the test command signal and couples an information signal to the antenna port corresponding with the antenna to be tested. The reader awaits receipt of the information signal from the tag.

These and other features and advantages of the invention, as well as the structure and operation of various embodiments of the invention, are described in detail below with reference to the accompanying drawings. It is noted that the invention is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS/FIGURES

The accompanying drawings, which are incorporated herein and form a part of the specification, illustrate the present invention and, together with the description, further serve to explain the principles of the invention and to enable a person skilled in the pertinent art to make and use the invention.

FIG. 1 shows an environment in which RFID readers communicate with an exemplary population of RFID tags.

FIG. 2A is an exemplary block diagram of receiver and transmitter portions of a RFID reader, according to an embodiment of the present invention.

FIG. 2B is an exemplary block diagram of a RFID reader having a signal generation element, according to an embodiment of the present invention.

FIG. 3 is an exemplary block diagram of a tag including an antenna test module, according to an embodiment of the present invention.

FIG. 4 is an exemplary block diagram of the antenna test module shown in FIG. 3, according to an embodiment of the present invention.

FIGS. 5-7 are methods of testing antenna(s) in a RFID tag, according to embodiments of the present invention.

The present invention will now be described with reference to the accompanying drawings. In the drawings, like reference numbers generally indicate identical, functionally similar, and/or structurally similar elements. The drawing in which an element first appears is indicated by the leftmost digit(s) in the reference number.

### DETAILED DESCRIPTION OF THE INVENTION

This specification discloses one or more embodiments that incorporate the features of this invention. The embodiment(s) described, and references in the specification to “one embodiment”, “an embodiment”, “an example embodiment”, etc., indicate that the embodiment(s) described may include a particular feature, structure, or characteristic, but every embodiment may not necessarily include the particular feature, structure, or characteristic. Moreover, such phrases are not necessarily referring to the same embodiment. Furthermore, when a particular feature, structure, or characteristic is described in connection with an embodiment, it is submitted that it is within the knowledge of one skilled in the art to effect such feature, structure, or characteristic in connection with other embodiments whether or not explicitly described.

### 1.0 Introduction

The present invention relates to radio frequency identification (RFID) technology. More specifically, embodiments of the invention include methods, systems, and apparatuses for testing RFID tags. The following section describes an exemplary RFID system. This section is followed by several sections describing exemplary readers and tags in which embodiments of the present invention may be implemented. Exemplary embodiments for testing multiple antennas are then described, followed by exemplary method embodiments.

### 2.0 Exemplary RFID System

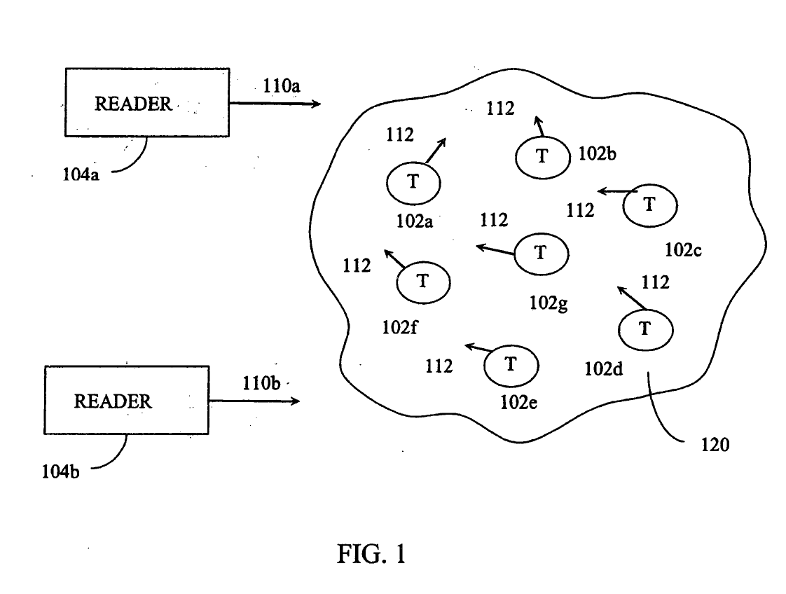

Before describing embodiments of the present invention in detail, it is helpful to describe an exemplary RFID communication environment in which the invention may be implemented. FIG. 1 illustrates an environment 100 in which RFID tag readers 104 communicate with an exemplary population 120 of RFID tags 102. As shown in FIG. 1, the population 120 of tags includes seven tags 102a-102g. A population 120 may include any number of tags 102.

Environment 100 includes any number of one or more readers 104. For example, environment 100 includes a first reader 104a and a second reader 104b. Readers 104a and/or 104b may be requested by an external application to address the population of tags 120. Alternatively, reader 104a and/or reader 104b may have internal logic that initiates communication, or may have a trigger mechanism that an operator of a reader 104 uses to initiate communication. Readers 104a-b may also communicate with each other in a reader network.

As shown in FIG. 1, reader 104a transmits an interrogation signal 110a having a first carrier frequency to the population of tags 120. Reader 104b transmits an interrogation signal 110b having a second carrier frequency to the population of tags 120. The first and second carrier frequencies may be the same or different. Readers 104a-b typically operate in one or more of the frequency bands allotted for this type of RF communication. For example, frequency bands of 902-928 MHz and 2400-2483.5 MHz have been defined for certain RFID applications by the Federal Communication Commission (FCC).

Various types of tags 102 may be present in tag population 120 that transmit one or more response signals 112 to an interrogating reader 104, including by alternatively reflecting and absorbing portions of signal 110a or 110b according to a time-based pattern or frequency. This technique for alternatively absorbing and reflecting signal 110a or 110b is referred to herein as backscatter modulation. Readers 104a-b receive and obtain data from response signals 112, such as an identification number of the responding tag 102. In the embodiments described herein, a reader may be capable of communicating with tags 102 according to any suitable communication protocol, including but not limited to binary traversal protocols, slotted aloha protocols, Class 0, Class 1, Electronic Product Code (EPC) Gen 2, any others mentioned elsewhere herein or otherwise known, and future communication protocols.

### 3.0 Exemplary Reader

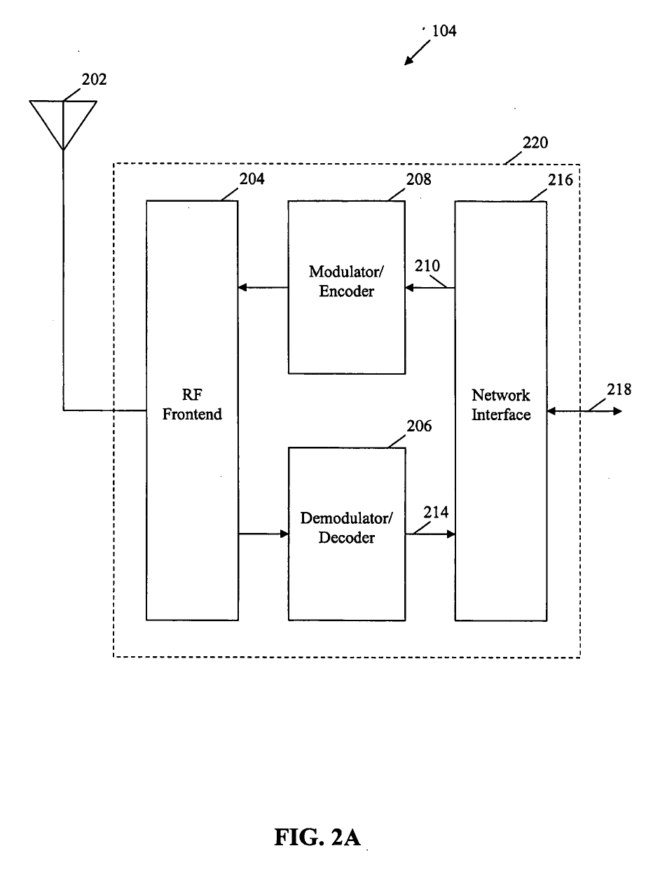

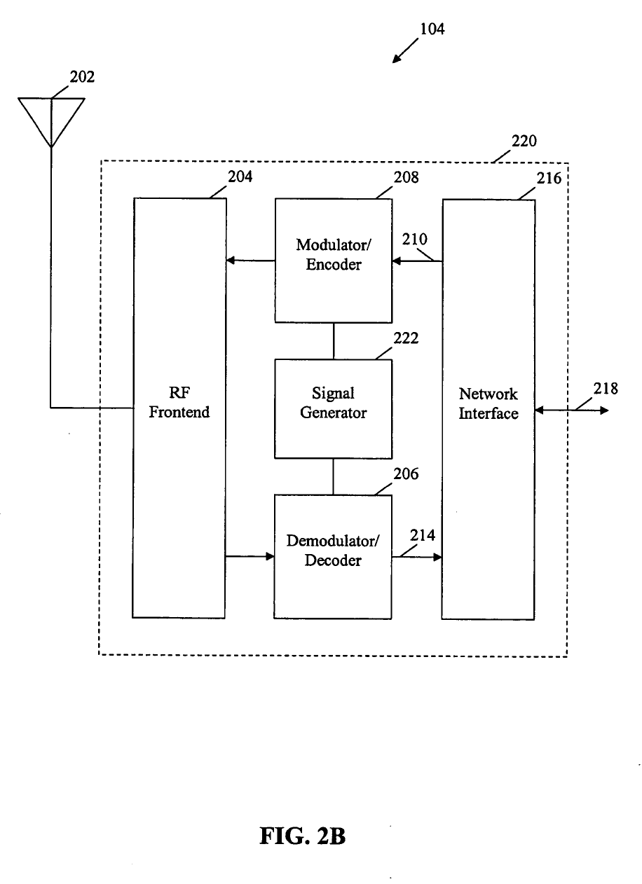

FIG. 2A is an exemplary block diagram of a receiver and transmitter portion 220 of a RFID reader 104, according to an embodiment of the present invention. Reader 104 includes one or more antennas 202, a RF front-end 204, a demodulator/decoder 206, a modulator/encoder 208, and an optional network interface 216. These components of reader 104 may include software, hardware, and/or firmware, or any combination thereof, for performing their functions.

Reader 104 has at least one antenna 202 for communicating with tags 102 and/or other readers 104. RF front-end 204 may include one or more antenna matching elements, amplifiers, filters, an echo-cancellation unit, a down-converter, and/or an up-converter, to provide some examples. RF front-end 204 receives a modulated encoded interrogation signal from modulator/encoder 208, up-converts (if necessary) the interrogation signal, and transmits the interrogation signal (shown as signal 110 in FIG. 1) to antenna 202 to be radiated. Furthermore, RF front-end 204 receives a tag response signal 112 through antenna 202 and down-converts (if necessary) response signal 112 to a frequency range amenable to further signal processing.

Modulator/encoder 208 is coupled to an input of RF front-end 204, and receives an interrogation request 210. Modulator/encoder 208 encodes interrogation request 210 into a signal format, such as one of FMO or Miller encoding formats, modulates the encoded signal, and provides the modulated encoded interrogation signal to RF front-end 204.

Demodulator/decoder 206 is coupled to an output of RF front-end 204, receiving a modulated tag response signal from RF front-end 204. Demodulator/decoder 206 demodulates the tag response signal. The tag response signal may include backscattered data encoded according to FMO or Miller encoding formats, or any other tag data formats. Demodulator/decoder 206 outputs a decoded data signal 214. Decoded data signal 214 may be further processed in reader 104. Additionally or alternatively, decoded data signal 214 may be transmitted to a subsequent computer system for further processing.

Reader 104 optionally includes network interface 216 to interface reader 104 with a communication network 218. When present, network interface 216 provides interrogation request 210 to reader 104, which may be received from a remote computer system coupled to communication network 218. Furthermore, network interface 216 transmits decoded data signal 214 from reader 104 to a remote computer system coupled to communication network 218.

According to example embodiments of the present invention, reader 104 is compatible with EPC™ Radio-Frequency Identity Protocols Class-1 Generation-2 UHF RFID Conformance Requirements Version 1.0.2, which is also known as “Gen2”, published by EPCglobal Inc. on Feb. 1, 2005. Gen2 allows custom commands to be used for communication between reader(s) 104 and tag(s) 102. In a first embodiment, a reader 104 provides the custom command to a tag 102 regardless of whether tag 102 supports the custom command. In this embodiment, tag 102 may discard the custom command if tag 102 does not support the custom command. In a second embodiment, reader 104 determines whether tag 102 supports a custom command before providing the custom command to tag 102.

In the second embodiment, reader 104 may determine an identification associated with a target tag 102 to facilitate determining whether target tag 102 supports the custom command. For instance, modulator/encoder 208 modulates a request signal. RF front-end 204 transmits the request signal to antenna 202 for transmission to target tag 102. After target tag 102 processes the request signal, reader 104 receives an identification signal from target tag 102 at antenna 202. Demodulator/decoder 206 demodulates the identification signal, allowing reader 104 to determine whether target tag 102 supports the custom command.

Upon determining that target tag 102 supports the custom command, reader 104 transmits the custom command to target tag 102. For example, different protocols may support different custom commands. In this example, reader 104 transmits the custom command based on whether the identification is associated with a manufacturer that supports the custom command.

FIG. 2B is an exemplary block diagram of a RFID reader 104 having a signal generator 222, according to an embodiment of the present invention. In FIG. 2B, signal generator 222 generates a test command signal to be sent to target tag 102. For example, the test command signal may include a parameter that indicates one or more antennas to be tested in target tag 102. According to one embodiment, the test command signal is a custom command signal in accordance with Gen2. Furthermore, the test command signal may include data with which the tag should respond if the antenna under test is operating properly.

Note that embodiments may be implemented in accordance with RFID communication protocols other than Gen2. Thus, embodiments are also applicable to readers and tags that communicate using protocols (proprietary or non-proprietary) mentioned elsewhere herein, and otherwise known.

### 4.0 Exemplary RFID Tag

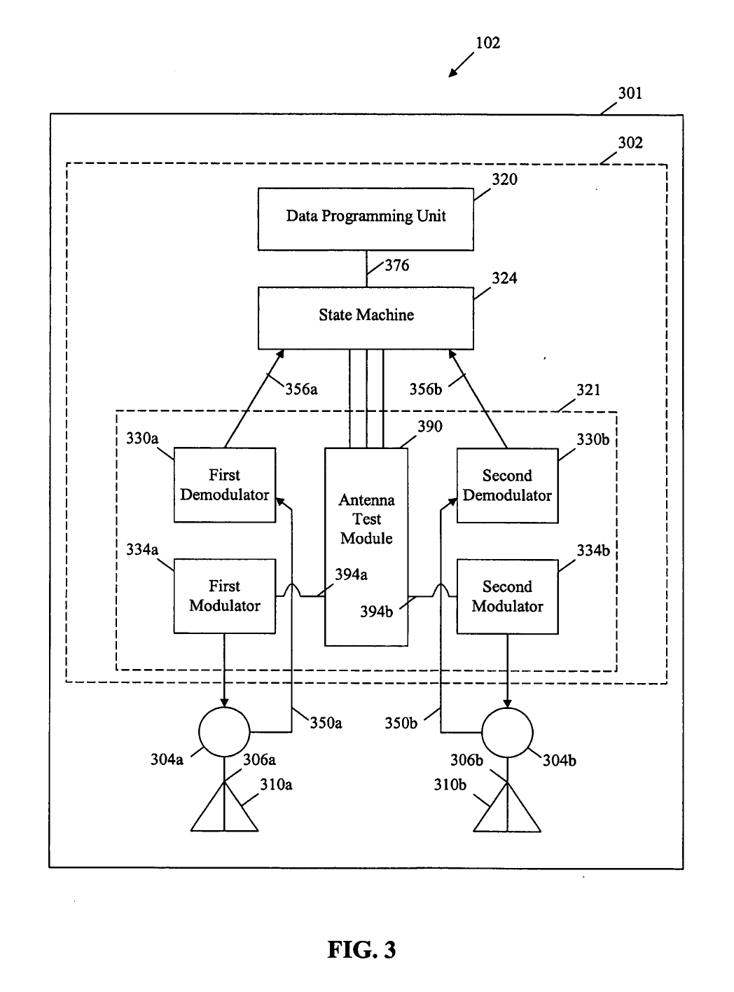

FIG. 3 is an exemplary block diagram of a tag 102, according to an embodiment of the present invention. Tag 102 includes an integrated circuit 302, first and second pads 304a-b, and first and second antennas 310a-b. These components are mounted or formed on a substrate 301 and are described in further detail below.

Pads 304 provide electrical connections between integrated circuit 302 and other components related to tag 102. For instance, first RF pad 304a establishes a connection between integrated circuit 302 and first antenna 310a. Second RF pad 304b provides a connection between integrated circuit 302 and second antenna 310b.

### 4.1 Tag Substrate

Integrated circuit 302 may be implemented across more than one integrated circuit chip, but is preferably implemented in a single chip. The one or more chips of integrated circuit 302 are created in one or more wafers made by a wafer fabrication process. Wafer fabrication process variations may cause performance differences between chips. For example, the process of matching inductances of a chip may be affected by fabrication process differences from wafer-to-wafer, lot-to-lot and die-to-die.

Integrated circuit 302 is mounted to substrate 301. In an embodiment, first and second antennas 310a-b are printed on substrate 301. In an embodiment, the materials used for substrate 301 are 3-5 Mil MYLAR™ or MYLAR™-like materials. The MYLAR™ related materials have relatively low dielectric constants and beneficial printing properties, as compared to many other materials. Conductive inks used to print an antenna design are cured at very high temperatures. These high temperatures can cause standard polymers to degrade quickly as well as become very unstable to work with.

An antenna design is printed on substrate 301 with the conductive inks. In an embodiment, the conductive inks are primarily silver particles mixed with various binders and solvents. For example, binders and solvents manufactured by DuPont Corporation may be used. The conductive inks can have different silver particle loads, which allows creation of the desired level of conductivity. Once an antenna is printed, the resistance or “Q” may be determined from the antenna design. A matching circuit may then be determined that allows a match of the surface of antennas 310a-b to first and second antenna pads 304a and 304b, respectively, providing an effective read range for tag 102. Antenna substrates of any type or manufacture may be used. For instance, subtractive processes that obtain an antenna pattern by etching or by removing material from a coated or deposited substrate may be used. In other instances, the antenna substrate may be eliminated altogether, and the antenna(s) may be incorporated directly into the integrated circuit.

Note that conductive materials by their own nature tend to oxidize, resulting in an oxide material forming on a surface of the conductive material. The oxide material can be conductive or non-conductive. Non-conductive oxides are detrimental to RF (UHF) performance, as they can significantly cause an antenna to detune. Therefore, a conductive material may be chosen that tends to oxidize with a conductive oxide. For example, the conductive material may be silver, nickel, gold, platinum, or other Nobel metal, as opposed to copper or aluminum, which tend to oxidize in a non-conductive fashion. However, any suitable material may be used for the conductive ink, including conductive materials that tend to oxide in a non-conductive fashion, such as those listed above.

### 4.2 Integrated Circuit

As shown in FIG. 3, integrated circuit 302 includes a data programming unit 320, a state machine 324, and an RF interface portion 321. Data programming unit 320 temporarily or permanently stores information that is received from state machine 324. The information may include an identification number associated with tag 102, a parameter that may be utilized in accordance with a custom command received from reader 104, or other information.

State machine 324 controls the operation of RFID tag 102, based on information received from data programming unit 320 and/or RF interface portion 321. For example, state machine 324 accesses data programming unit 320 via a bus 376 to determine whether tag 102 is to transmit a logical “1”, a logical “0”, or combinations of “1” and “0” bits. In this example, an identification number associated with tag 102 is stored in data programming unit 320, and state machine 324 accesses one or more bits of the identification number to make the determination. The one or more accessed bits allow state machine 324 to determine whether reader 104 is addressing tag 102 during the present portion of the current binary traversal, and what response, if any, is appropriate. State machine 324 may include software, firmware, and/or hardware, or any combination thereof. For example, state machine 324 may include digital circuitry, such as logic gates.

RF interface portion 321 is coupled to first and second antennas 310a-b to provide a bi-directional communication interface with reader 104. In an embodiment, RF interface portion 321 includes components that modulate digital information symbols into RF signals, and demodulate RF signals into digital information symbols. In another embodiment, RF interface portion 321 includes components that convert a wide range of RF power and voltage levels in the signals received from first and second antennas 310a-b into usable signals. For example, the signals may be converted to the form of transistor usable direct current (DC) voltage signals that may have substantially greater or lesser magnitudes than signals radiated to reader 104 by first and second antennas 310a-b.

Referring to FIG. 3, RF interface portion 321 includes first and second demodulators 330a-b, first and second modulators 334a-b, and an antenna test module 390. First demodulator 330a and first modulator 334a are coupled to first antenna 310a. Second demodulator 330b and second modulator 334b are coupled to second antenna 310b. In the embodiment of FIG. 3, first and second modulators 334a-b perform backscatter modulation of data from state machine 324.

In an embodiment, first and second modulators 334a-b each include a switch, such as a single pole, single throw (SPST) switch. The switch changes the return loss of the respective one of first and second antennas 310a-b. The return loss may be changed in any of a variety of ways. For example, the RF voltage at the respective antenna when the switch is in an “on” state may be set lower than the RF voltage at the antenna when the switch is in an “off” state by a predetermined percentage (e.g., 30 percent). This may be accomplished by any of a variety of methods known to persons skilled in the relevant art(s).

In the example embodiment of FIG. 3, first and second demodulators 330a-b demodulate and provide respective first and second received signals 356a-b to state machine 324.

It will be recognized by persons skilled in the relevant art(s) that RF interface portion 321 may include any number of modulator(s) and/or demodulator(s). Accordingly, the present invention allows for a single RF signal to be received and processed, and for any number of two or more RF signals to be simultaneously received and processed.

### 5.0 Exemplary Embodiments for Testing Multiple Antennas

Antenna test module 390 facilitates testing of antenna(s) 310a and/or 310b based on a test command signal received from reader 104. The test command signal indicates which of antennas 310a and/or 310b is to be tested. The test command signal may be compatible with a communication protocol, though the scope of the present invention is not limited in this respect. For example, the test command signal may be a custom command signal in accordance with Gen2, as described in section 3.0 above.

As shown in FIG. 3, antenna test module 390 is coupled to state machine 324, first modulator 334a, and second modulator 334b. When a reader directs tag 102 to test antenna 310a, state machine 324 provides a signal to antenna test module 390 to enable first modulator 334a and disable second modulator 334b. Thus, first modulator 334 modulates a signal to be transmitted by antenna 310a. When a reader directs tag 102 to test antenna 310b, state machine 324 provides a signal to antenna test module 390 to enable second modulator 334b and disable first modulator 334a. Thus, second modulator 334b modulates a signal to be transmitted by antenna 310b.

If the antenna that is enabled to transmit is defective, including if the antenna is damaged, if the antenna is not coupled to its respective antenna pad properly, if the corresponding pad of die 302 is not coupled to the respective antenna pad properly, etc., the antenna will fail the test, and the reader will not receive a response. Thus, the defective tag can be checked for a defect, and the defect can be corrected, or the tag can be disposed of or recycled.

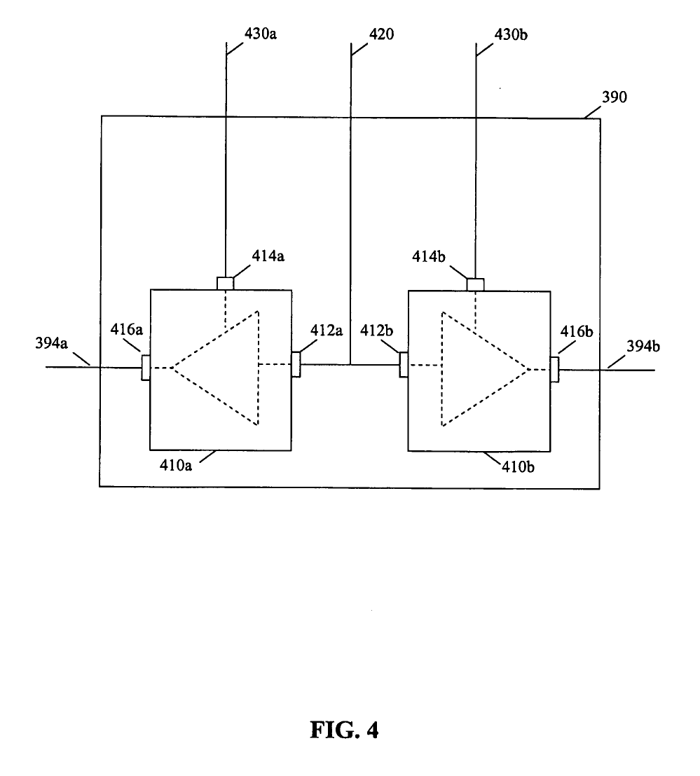

FIG. 4 is an exemplary block diagram of antenna test module 390, according to an embodiment of the present invention. In FIG. 4, antenna test module 390 includes first enabling element 410a and second enabling element 410b. First enabling element 410a includes a first input port 412a, a first control port 414a, and a first output port 416a. Second enabling element 410b includes a second input port 412b, a second control port 414b, and a second output port 416b. First and second enabling elements 410a-b receive an information signal 420 from state machine 324 via respective input ports 412a-b.

First enabling element 410a receives a first test control signal 430a from state machine 324 at first control port 414a. Second enabling element 410b receives a second test control signal 430b from state machine 324 at second control port 414b. First enabling element 410a selectively provides information signal 420 at first output port 416a based on first test control signal 430a. Second enabling element 410b selectively provides information signal 420 at second output port 416b based on second test control signal 430b.

First enabling element 410a is configured to couple information signal 420 to first output port 416a when first test control signal 430a has a first value (e.g., a “1” or a “0”, or a “high” or a “low”). Information signal 420 is not coupled to first output port 416a by first enabling element 410a when first test control signal 430a has a second value, which is different from the first value.

Second enabling element 410b is configured to couple information signal 420 to second output port 416b when second test control signal 430b has a first value. Information signal 420 is not coupled to second output port 416b by second enabling element 410b when second test control signal 430b has a second value, which is different from the first value.

In FIG. 4, antenna test module 390 is shown to include two enabling elements 410a-b for illustrative purposes. Antenna test module 390 may include any number of enabling elements depending on the number of antennas present. First and second enabling elements 410a-b are shown to be buffers in FIG. 4 for illustrative purposes. First and second enabling elements 410a-b may be any type of element that is capable of selectively coupling information signal 420 to respective output ports 416a-b (e.g., a switch, other logic gates, etc.). First and second enabling elements 410a-b may be implemented using software, firmware, or hardware, or any combination thereof.

### 6.0 Exemplary Methods

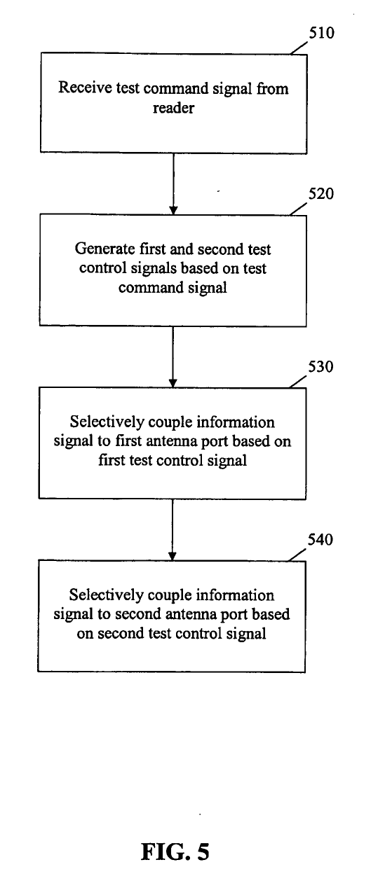

FIGS. 5-7 illustrate flowcharts 500, 600, and 700 of methods for testing antenna(s) of an RFID tag according to embodiments of the present invention. The invention, however, is not limited to the description provided by flowcharts 500, 600, or 700. Rather, it will be apparent to persons skilled in the relevant art(s) from the teachings provided herein that other functional flows are within the scope and spirit of the present invention.

Flowcharts 500, 600, and 700 will be described with continued reference to example reader 104 described above in reference to FIGS. 2A-2B and example tag 102 described above in reference to FIGS. 3-4. The invention, however, is not limited to these embodiments.

Referring now to FIG. 5, at block 510, a test command signal is received from a reader. For example, in an embodiment, tag 102 receives a test command signal from reader 104. The test command signal may be a custom command in accordance with Gen2 or another communication protocol, though the scope of the present invention is not limited in this respect. In tag 102, antennas 310a-b receive the test command signal and provide the test command signal to first and second demodulators 330a-b for processing. For instance, first and second demodulators 330a-b may down-convert and/or decode the test command signal.

At block 520, first and second test control signals are generated based on the test command signal. For example, in an embodiment, state machine 324 generates first and second test control signals 430a-b based on the test command signal. In an aspect, state machine 324 further generates an information signal 420 based on the test command signal. Alternatively, state machine 324 receives information signal 420 from first demodulator 330a and/or second demodulator 330b.

At block 530, an information signal is selectively coupled to a first antenna port based on the first test control signal. For example, in an embodiment, antenna test module 390 selectively couples information signal 420 to first antenna port 306a based on first test control signal 430a. In an aspect, first modulator 334a up-converts and/or encodes information signal 420, which is then provided to first antenna port 306a.

At block 540, the information signal is selectively coupled to a second antenna port based on the second test control signal. For example, in an embodiment, antenna test module 390 selectively couples information signal 420 to second antenna port 306b based on second test control signal 430b. In an aspect, second modulator 334b up-converts and/or encodes information signal 420, which is then provided to second antenna port 306a. In FIG. 5, steps 530 and 540 may be performed simultaneously, though the scope of the present invention is not limited in this respect.

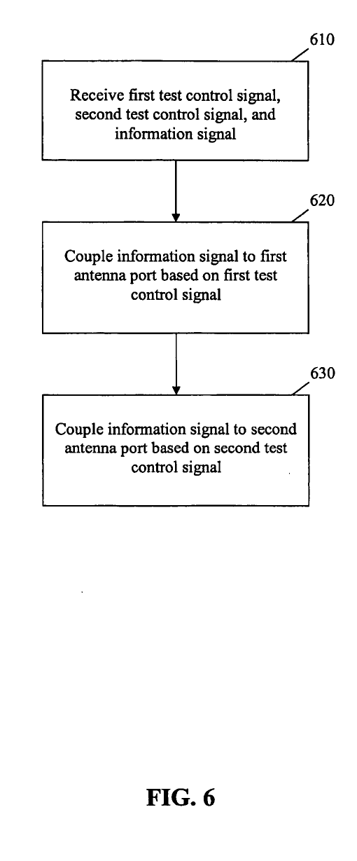

FIG. 6 shows another embodiment that may be implemented from the perspective of a tag. In FIG. 6, at block 610, a first test control signal, a second test control signal, and an information signal are received. For example, in an embodiment, antenna test module 390 receives first test control signal 430a, second test control signal 430b, and information signal 420.

At block 620, the information signal is coupled to a first antenna port based on the first test control signal. For example, in an embodiment, first enabling element 410a couples information signal 420 to first antenna port 306a based on first test control signal 430a.

At block 630, the information signal is coupled to a second antenna port based on the second test control signal. For example, in an embodiment, second enabling element 410b couples information signal 420 to second antenna port 306b based on second test control signal 430b.

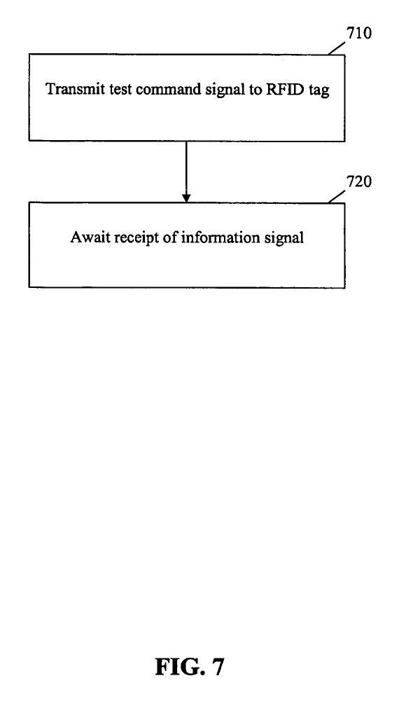

FIG. 7 shows an embodiment that may be implemented from the perspective of a reader. In FIG. 7, at block 710, a test command signal is transmitted to an RFID tag. For example, in an embodiment, reader 104 transmits a test command signal to RFID tag 102.

At block 720, receipt of an information signal is awaited. For example, in an embodiment, reader 104 awaits receipt of an information signal 420. In this embodiment, receipt of information signal 420 by reader 104 indicates that information signal 420 is coupled to first antenna 310a. Lack of receipt of information signal 420 by reader 104 indicates that information signal 420 is not coupled to first antenna 310a.

The methods described above with reference to FIGS. 5-7 may be used to determine whether each of a plurality of antennas in an RFID tag, such as antennas 310a-b in tag 102, is electrically coupled to a respective antenna port, such as antenna port 306a or 306b.

### 7.0 Other Embodiments

FIGS. 1-7 are conceptual illustrations providing a description of testing antenna(s) of a RFID tag, according to embodiments of the present invention. It should be understood that embodiments of the present invention can be implemented in hardware, firmware, software, or a combination thereof. In such an embodiment, the various components and steps are implemented in hardware, firmware, and/or software to perform the functions of that embodiment. That is, the same piece of hardware, firmware, or module of software can perform one or more of the illustrated blocks (i.e., components or steps).

Persons of ordinary skill in the art will recognize that embodiments of the present invention enable antennas 310a-b to be independently tested. For example, reader 104 and/or tag 102 may test antenna 310a and then antenna 310b, or vice versa. In other embodiments, antennas 310a-b are tested together. In one such embodiment, reader 104 transmits a first test command signal to tag 102. The first test command signal includes information (e.g., a parameter) that enables integrated circuit 302 to couple a first information signal to first antenna port 306a and second antenna port 306b, such that first and second antennas 310a-b both provide the first information signal to reader 104. According to an embodiment, after reader 104 receives the first information signal from tag 102, reader 104 transmits a second test command signal to tag 102, which includes information that enables a second information signal to be coupled to either first antenna port 306a or second antenna port 306b. In this embodiment, either first antenna 310a provides the second information signal to reader 104 or second antenna 310b provides the second information signal to reader 104. Reader 104 and/or tag 102 may be capable of alternating between testing both antennas 310a-b together and a single antenna 306a or 306b.

According to another embodiment, reader 104 solicits an information signal from tag 102 to determine whether tag 102 is at least partially operational. In this embodiment, reader transmits a test command signal that enables the information signal to be coupled to both the first and second antenna ports 306a-b. After receiving the information signal from tag 102, and thereby determining that tag 102 is at least partially operational, reader 102 may solicit another information signal from tag 102 to determine whether a particular antenna 310a or 310b of tag 102 is sufficiently operational.

In order to test the particular antenna 310a or 310b, reader 104 transmits a second test command signal that enables a second information signal to be coupled to an antenna port 306a or 306b corresponding with the particular antenna 310a or 310b to be tested. The other antenna port is not coupled to the second information signal. If reader 104 detects the second information signal, then reader 104 determines that the particular antenna 310a or 310b is sufficiently operational. Otherwise, reader 104 determines that the particular antenna 310a or 310b is not sufficiently operational.

The failure of reader 104 to detect the second information signal may indicate that an electrical connection between integrated circuit 302 and the particular antenna 310a or 310b is broken. For instance, this may be due to a manufacturing error, the tag may have been tampered with, or there may have been tampering with an object to which the tag 102 is affixed.

For example, in a tamper proofing embodiment, tag 102 may be coupled to an item. If packaging of the item is opened, and/or if interaction with the item otherwise occurs, tag 102 may be configured such that a connection between integrated circuit 302 and antenna 108a or 108b will be broken. Thus, if during testing, antenna 108a or 108b does not respond, this may be an indication that tampering with tag 102 has occurred. A trace between integrated circuit 302 and antenna 108a or 108b may be routed through the packaging, through the item itself, or in some other way such that the trace is broken when interaction with the item occurs.

### 8.0 Conclusion

While various embodiments of the present invention have been described above, it should be understood that they have been presented by way of example, and not limitation. It will be apparent to persons skilled in the relevant arts that various changes in form and detail can be made therein without departing from the spirit and scope of the invention. Thus, the present invention should not be limited by any of the above-described exemplary embodiments, but should be defined only in accordance with the following claims and their equivalents.

What is claimed is:

1. A method of testing antenna(s) of a radio frequency identification (RFID) tag having a first antenna coupled to a first antenna port and a second antenna coupled to a second antenna port, comprising:
(a) receiving a test command signal from a reader;
(b) generating first and second test control signals based on the test command signal;
(c) selectively coupling an information signal to the first antenna port based on the first test control signal; and
(d) selectively coupling the information signal to the second antenna port based on the second test control signal.

2. The method of claim 1, wherein step (a) includes receiving a custom command in accordance with Gen2.

3. The method of claim 1, wherein step (a) comprises receiving in the test command signal an indication to test a characteristic of the first antenna.

4. The method of claim 3, wherein step (c) includes coupling the information signal to the first antenna port, and wherein step (d) includes decoupling the information signal from the second antenna port.

5. The method of claim 4, wherein lack of transmission of the information signal at the first antenna indicates tampering with an object to which the first antenna is affixed.

6. The method of claim 5, wherein a connection between the first antenna port and the first antenna is configured to be broken when interaction with the object occurs.

7. A method of testing antenna(s) of a radio frequency identification (RFID) tag having an integrated circuit, a first antenna, and a second antenna, comprising:
transmitting a test command signal to the radio frequency identification (RFID) tag; and
awaiting receipt of an information signal in response to said transmitting the test command signal;
wherein receipt of the information signal indicates that the information signal is coupled to the first antenna; and
wherein lack of receipt of the information signal indicates that the information signal is not coupled to the first antenna.

8. The method of claim 7, wherein transmitting the test command signal includes transmitting a custom command in accordance with an EPC Gen2 communication protocol.

9. The method of claim 7, further comprising:
determining whether the RFID tag supports the test command, wherein the transmitting step is performed if the RFID tag is determined to support the test command.

10. The method of claim 9, wherein the determining step is performed based on an identification number associated with the RFID tag.

11. The method of claim 7, further comprising:
enabling the integrated circuit to decouple the information signal from a second antenna port that is coupled to the second antenna.

12. The method of claim 7, further comprising:
enabling the integrated circuit to couple the information signal to a first antenna port that is coupled to the first antenna.

13. The method of claim 7, wherein lack of receipt of the information signal indicates tampering with an object to which the first antenna is affixed.

14. A radio frequency identification (RFID) tag reader configured to test antennas of an RFID tag having a first antenna port coupled to a first antenna and a second antenna port coupled to a second antenna, comprising:
means for generating a test command signal including a parameter, wherein the parameter indicates which one of the first antenna or the second antenna is to be tested;
means for transmitting the test command signal to the RFID tag; and
means for receiving an information signal from the RFID tag in response to the transmitted test command signal.

15. The RFID tag reader of claim 14, wherein the test command signal is a custom command signal in accordance with an EPC Gen2 communication protocol.

16. The RFID tag reader of claim 14, further comprising:
means for determining whether the RFID tag supports the test command signal.

17. The RFID tag reader of claim 16, wherein the means for determining is configured to determine whether the RFID tag supports the test command signal based on an identification number associated with the RFID tag.

18. A radio frequency identification (RFID) tag, comprising:
a first antenna port coupled to a first antenna;
a second antenna port coupled to a second antenna;
a first enabling element configured to selectively couple an information signal to the first antenna port based on a first test control signal;
a second enabling element configured to selectively couple the information signal to the second antenna port based on a second test control signal;
wherein the first and second test control signals are based on a test command signal received from a tag reader.

19. The RFID tag of claim 18, wherein the first enabling element is a first buffer, and wherein the second enabling element is a second buffer.

20. The RFID tag of claim 18, wherein the test command signal is a custom command signal in accordance with an EPC Gen2 communication protocol.

21. The RFID tag of claim 18, further comprising:
a state machine to generate the first test control signal and the second test control signal based on the custom command.

22. The RFID tag of claim 18, wherein the first antenna is coupled to an object, and wherein a connection between the first antenna port and the first antenna is configured to be broken when tampering with the object occurs.

23. A method of testing antennas of a radio frequency identification (RFID) tag having a first antenna coupled to a first antenna port and a second antenna coupled to a second antenna port, comprising:
receiving first and second test control signals and an information signal;
coupling the information signal to the first antenna port based on the first test control signal; and
coupling the information signal to the second antenna port based on the second test control signal.

24. The method of claim 23, further comprising:
generating the first and second test control signals based on an EPC Gen2 custom command signal received from a reader.

25. The method of claim 23, wherein lack of transmission of the information signal at the first antenna indicates tampering with an object to which the first antenna is affixed.
